(19) United States
(12) Patent Application Publication
(10) Pub. No.: US 2008/0290348 A1
(43) Pub. Date: Nov. 27, 2008

(54) Semiconductor device

(75) Inventor: Toru Yoshie, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD.

(21) Appl. No.: 12/081,915

(22) Filed: Apr. 23, 2008

(30) Foreign Application Priority Data
May 24, 2007 (JP) 2007-137302

(51) Int. Cl. H01L 31/0312

(52) U.S. Cl. 257/77; 257/E21.055

(57) ABSTRACT

In the present invention, a vertical MOSFET is formed by growing epitaxial Si on a SiC substrate and forming a Si oxide layer on the Si. In particular, a semiconductor device according to the present invention includes a SiC substrate, and an epitaxial Si layer formed on a surface of the SiC substrate, and a Si oxide layer formed on the epitaxial Si layer, and a gate electrode formed on the Si oxide layer, and a source region formed in the epitaxial Si layer, and a drain electrode connected to the SiC substrate.

### CROSS REFERENCE TO RELATED APPLICATION

This application claims the priority of Application No. 2007-137302, filed May 24, 2007 in Japan, the subject matter of which is incorporated herein by reference.

### TECHNICAL FIELD OF THE INVENTION

The present invention relates to a semiconductor device and a method for fabricating the same. In particular, the present invention relates to a configuration in a vicinity of a gate oxide layer of a metal oxide semiconductor field effect transistor (MOSFET) fabricated using a SiC substrate.

### BACKGROUND OF THE INVENTION

Semiconductor devices using SiC crystals characteristically operate better at high voltages and high temperatures than semiconductor devices using Si crystals. This improved performance is because carbon atoms decrease the distance between atoms, strengthen bonds, and increase the semiconductor band gap by more than double. As a result, the pressure rises to more than double the electrical field, and semiconductor properties are retained even at high temperatures.

FIG. 1 is a cross-sectional view of a conventional high voltage SiC device. In this figure, an aluminum gate 24 and a source electrode (aluminum electrodes) 18 is formed on an upper surface of the device, and a drain electrode (not illustrated) is formed on a lower surface of a substrate. Such a configuration allows an electrical potential of a strong electric field in the vertical direction between the source and the drain. An electrical potential of several hundred V to several tens kV is applied across SiC material junctions. Conversely, an electrical potential of several tens V applied to the aluminum gate 24 is used to switch the MOSFET on and off. In this case, an electric field of a maximum intensity of about 3 MV/cm is designed to be applied to a gate insulating layer 14.

FIG. 1 also illustrates an N-type SiC substrate 10, a P-well region 12, a polysilicon gate electrode 16, a P⁺ impurity diffusion region 20, an N⁺ impurity diffusion region 22, and inter-layer insulating layers 26a and 26b.

FIG. 2 is a cross-sectional view enlarging the region (defined by the broken line in FIG. 1), illustrating a vicinity of a gate oxide layer 14a on the N⁺ impurity diffusion region 22. In the case of a silicon oxide layer 14 formed in an oxygen atmosphere by heating, the silicon oxide layer 14a on the N⁺ impurity diffusion region 22 is thicker than the silicon oxide layer 14 formed on both the P-type well region 12 and the SiC substrate 10. The quality of the silicon oxide layer 14a on such an N⁺ impurity diffusion region 22 is poor. The poor quality is due to oxidation of a substrate implanted with a high-concentration N⁺ impurity (phosphorus) causing migration of phosphorus into the oxide layer; such oxidation also harms the insulating abilities of the oxide layer due to precipitation of phosphorus into the interface between the oxide layer and Si. Decreased quality of the gate oxide layer may cause poor semiconductor device yields. As discussed below, evaluations of long-term reliability indicate problems due to poor endurance of the silicon oxide layer 14a on the N⁺ impurity diffusion region 22.

FIG. 3 and FIG. 4 present reliability data of a gate oxide layer. This data evaluates time dependent dielectric breakdown (TDDB) at constant electric potential at 250° C. for a thermal oxide layer formed on a 4H—SiC substrate. FIG. 3 illustrates the case of an N⁺ impurity diffusion region (22) formed by highly concentrated phosphorus implantation (injection), and a thermal oxide layer formed thereupon. FIG. 4 illustrates the case of a thermal oxide layer formed on the SiC substrate without implantation (injection) of phosphorus. As illustrated in FIG. 3, TDDB duration is short with large variation for the thermal oxide layer (14a) on the N⁺ impurity diffusion region (22).

FIGS. 5A to 5I illustrate steps for fabricating the conventional semiconductor device illustrated in FIG. 1 and FIG. 2. A mask of a desired pattern (not illustrated) is formed on an N-type SiC substrate 10 (FIG. 5A), and a P-well region 12 is formed therein by ion injection as illustrated in FIG. 5B.

Thereafter, an N⁺ impurity diffusion region 22 and a P⁺ impurity diffusion region 20 are formed similarly by ion injection (FIG. 5C). If necessary, further ion implantation may be performed to change the transistor threshold, form a guard ring for surface field relaxation, etc. Ions types may include aluminum to form the P-type regions and nitrogen and phosphorus to form the N-type regions.

Then, an activation heat treatment is performed at about 1200° C. to 1800° C., after which an inter-layer insulating layer 26a is formed to separate elements (FIG. 5D). It is general practice to form the inter-layer insulating layer 26a by CVD oxide layer followed by a thermal oxide layer formed thereupon, but the stability of the SiC surface can be improved by forming the CVD oxide layer after forming the thermal oxide layer. As illustrated in FIG. 6E, an aperture 28 is made in the element region of the inter-layer insulating layer 26a. Thermal oxidation then forms a silicon oxide layer 14 on the element region as illustrated in FIG. 6F.

Thereafter, a polysilicon gate electrode layer 16 is formed (patterning) on the silicon oxide layer 14 by well-known methods as illustrated in FIG. 7G. An inter-layer insulating layer 26b is formed by well-known methods as illustrated in FIG. 7H. Finally, aluminum electrode layers 18 and 24 are formed by well-known methods as illustrated in FIG. 7I.

For conventional semiconductor devices, as stated above, the TDDB duration of the thermal oxide layer 14a on the N⁺ impurity diffusion region 22 illustrated in FIG. 2, has the problem of short and large variations.

Patent document 1 discloses a vertical MOSFET including epitaxial Si grown on a Si substrate. Furthermore, Patent document 2 discloses an invention of growing epitaxial Si on a SiC substrate and forming a silicon oxide layer by oxidation thereupon.
[Patent document 1] Patent Laid Open No. H05-243275 official gazette
[Patent document 2] Patent Laid Open No. 2003-124208 official gazette

### OBJECTS OF THE INVENTION

In consideration of the situation described above, an objective of the present invention is to provide a semiconductor device having improved reliability of the gate oxide layer.

Another objective of the present invention is to provide a method for fabricating a semiconductor device having improved reliability of the gate oxide layer.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

The present invention is characterized by a vertical MOSFET, an epitaxial Si (130) grown on the SiC substrate (110), and a silicon oxide layer formed on the Si (130).

According to a first aspect of the present invention, a semiconductor device includes: a SiC substrate; an epitaxial Si layer formed on a surface of the SiC substrate; a Si oxide layer formed on the epitaxial Si layer; a gate electrode formed on the Si oxide layer; a source region formed in the epitaxial Si layer; and a drain electrode connected to the SiC substrate.

According to a second aspect of the present invention, a method for fabricating a semiconductor device comprises the steps of: forming a well region of a second conduction type in a SiC substrate of a first conduction type; growing a Si layer of the first conduction type in the well region; forming a gate insulating layer on the Si layer; forming a gate electrode on the gate insulating layer; and forming a source region in the Si layer in a self-aligning fashion in regards to the gate electrode.

In the second aspect of the present invention, preferably, the SiC substrate is selected from a 3C—SiC (cubic silicon carbide) substrate, a 4H—SiC substrate, and a 6H—SiC substrate.

According to a third aspect of the present invention, a method for fabricating a semiconductor device comprises the steps of: forming a well region of a second conduction type in a SiC substrate of a first conduction type; forming a trench in an element formation region of the well region; filling the trench with monocrystalline or polycrystalline silicon; and forming a source region of the first conduction type in the silicon portion filled in the trench.

In the second aspect of the present invention, preferably, a gate insulating layer is formed on the silicon layer filled in the trench.

Preferably, the SiC substrate is selected from a 3C—SiC (cubic silicon carbide) substrate, a 4H—SiC substrate, and a 6H—SiC substrate.

The present invention improves the quality and performance of the gate oxide layer, thereby improving the reliability of the semiconductor device. In other words, in the present invention, the gate oxide layer is formed on an epitaxial Si layer, thereby greatly improving yield and reliability of the gate oxide layer. In addition, because a MOSFET (source region) is formed in the epitaxial Si layer, the on resistance can be reduced, compared to that of conventional art.

The above stated Patent document 2 has an objective of improving an interface between the SiC substrate and the silicon oxide layer, and does not include a configuration similar to a SiC substrate—epitaxial Si layer—silicon oxide layer configuration. Furthermore, Patent document 1 employs a Si substrate and does not solve the problems particular to a vertical MOSFET employing a SiC substrate, as does the present invention.

Also, in methods of fabricating conventional vertical MOSFET having the silicon oxide layer formed on the SiC substrate, a diffusion region is formed by simultaneous heating and ion injection prior to forming the gate oxide layer. Conversely, the present invention includes a gate oxide layer formed on an epitaxial Si layer and therefore does not require the conventional step of simultaneous heating and ion injection. Thus, the diffusion region may be formed in a self-aligning fashion after forming the gate.

### BRIEF DESCRIPTION OF THE DRAWINGS

FIG. 1 is a cross-sectional view illustrating a portion of a conventional semiconductor device.

FIG. 2 is a cross-sectional view illustrating details of the region enclosed by the broken line in FIG. 1.

FIG. 3 illustrates gate oxide layer reliability data. The data is for the case of an N⁺ impurity diffusion region formed by highly concentrated implantation (injection) of phosphorus, and a thermal oxide layer formed thereupon.

FIG. 3 illustrates gate oxide layer reliability data for the case of a thermal oxide layer formed on a SiC substrate without implantation (injection) of impurities.

FIGS. 5A to 5I are cross-sectional views illustrating steps for fabricating the conventional semiconductor device illustrated in FIG. 1 and FIG. 2.

FIG. 6 is a cross-sectional view illustrating a portion of a semiconductor device according to a first embodiment of the present invention.

FIG. 7 is a cross-sectional view illustrating details of the region enclosed by the broken line in FIG. 6.

FIGS. 8A to 8I are cross-sectional views illustrating steps for fabricating a semiconductor device according to the first embodiment of the present invention illustrated in FIG. 6 and FIG. 7.

FIG. 9 is a cross-sectional view illustrating a portion of a semiconductor device according to a second embodiment of the present invention.

FIG. 10 is a cross-sectional view illustrating details of the region enclosed by the broken line in FIG. 9.

FIGS. 11A to 11J are cross-sectional views illustrating steps for fabricating a semiconductor device according to the second embodiment of the present invention illustrated in FIG. 9 and FIG. 10.

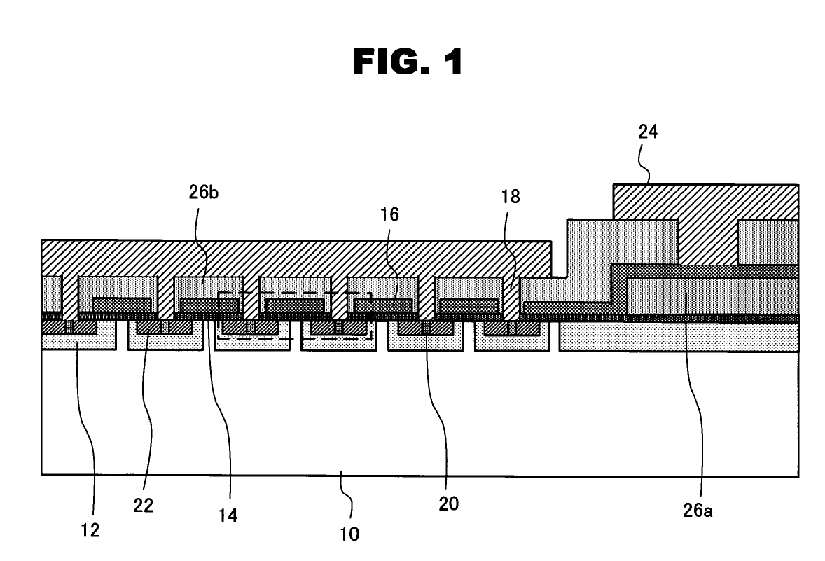

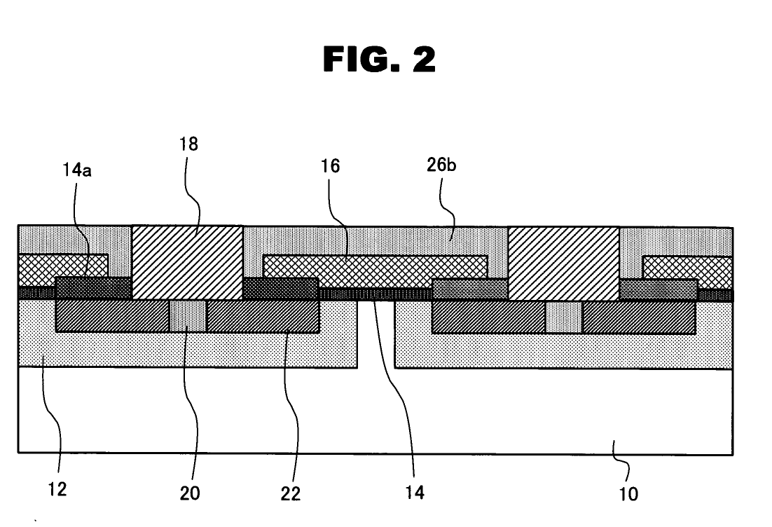

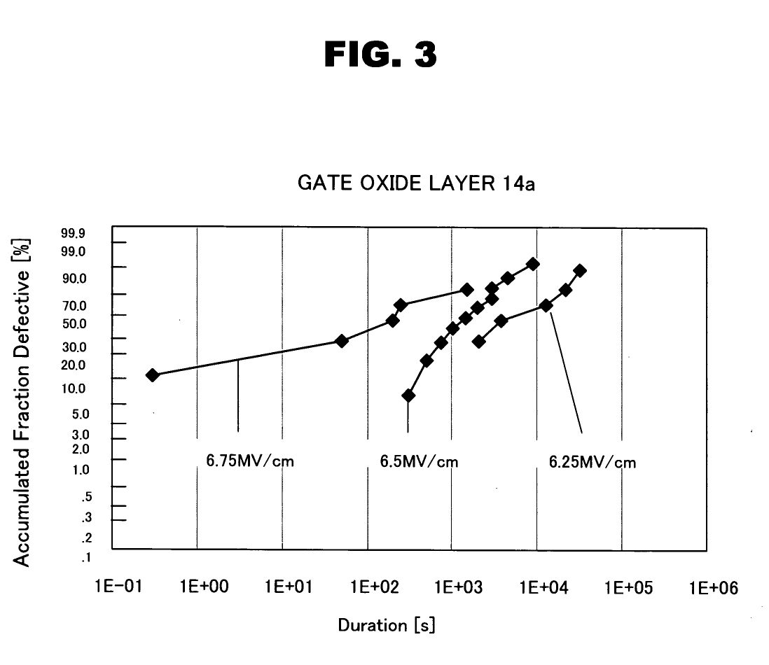

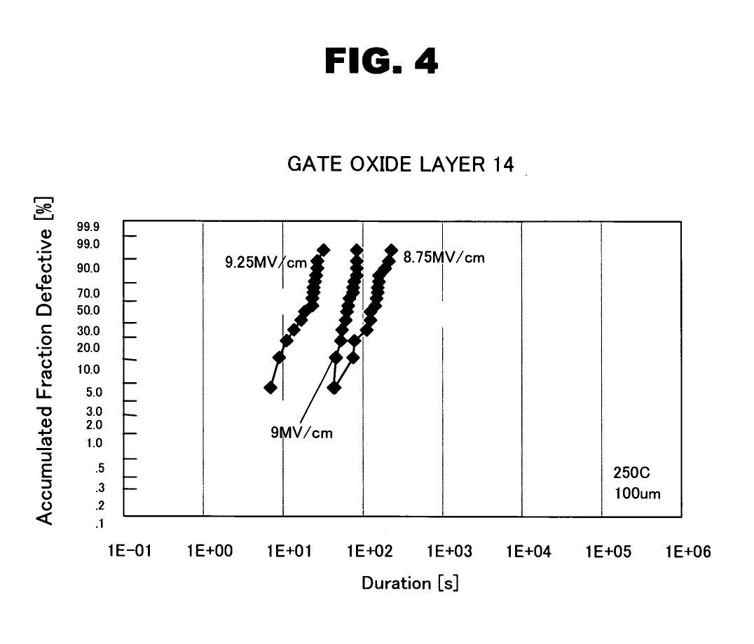

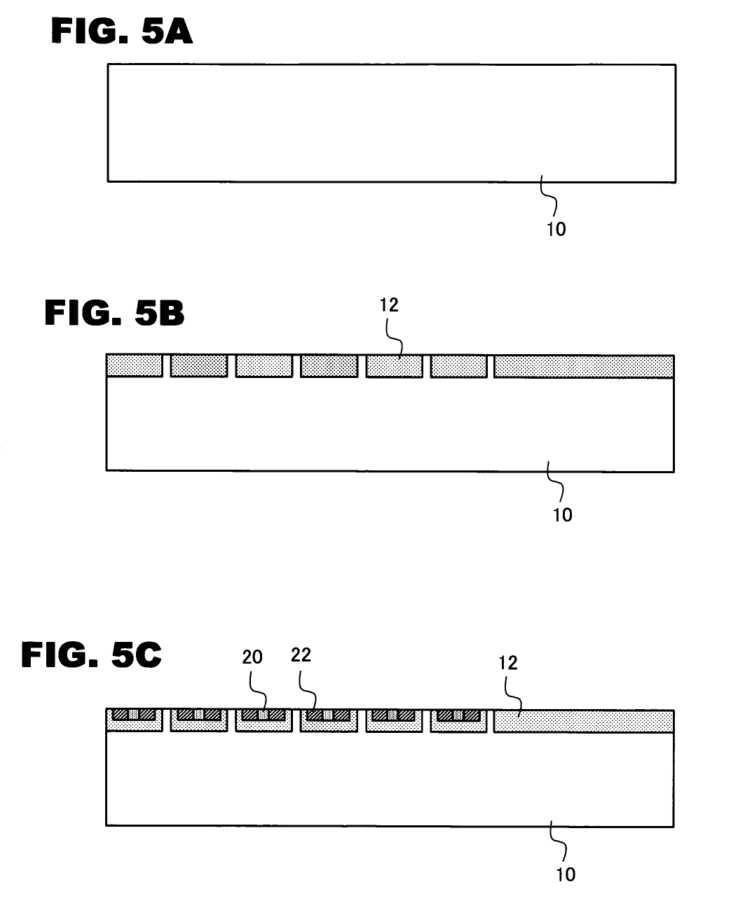

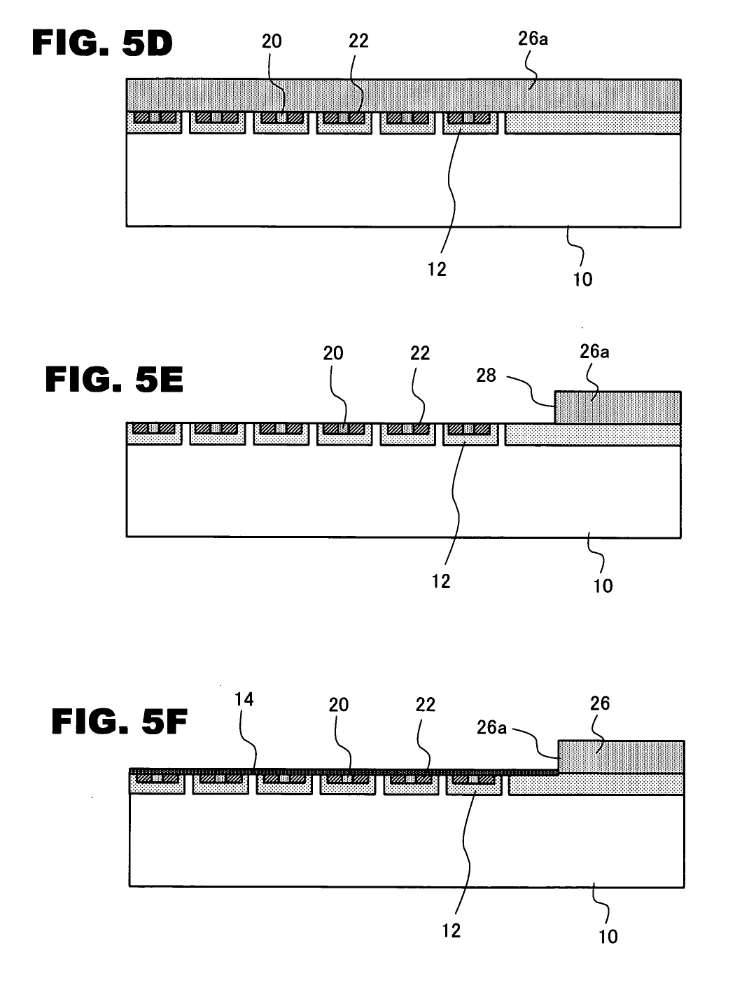

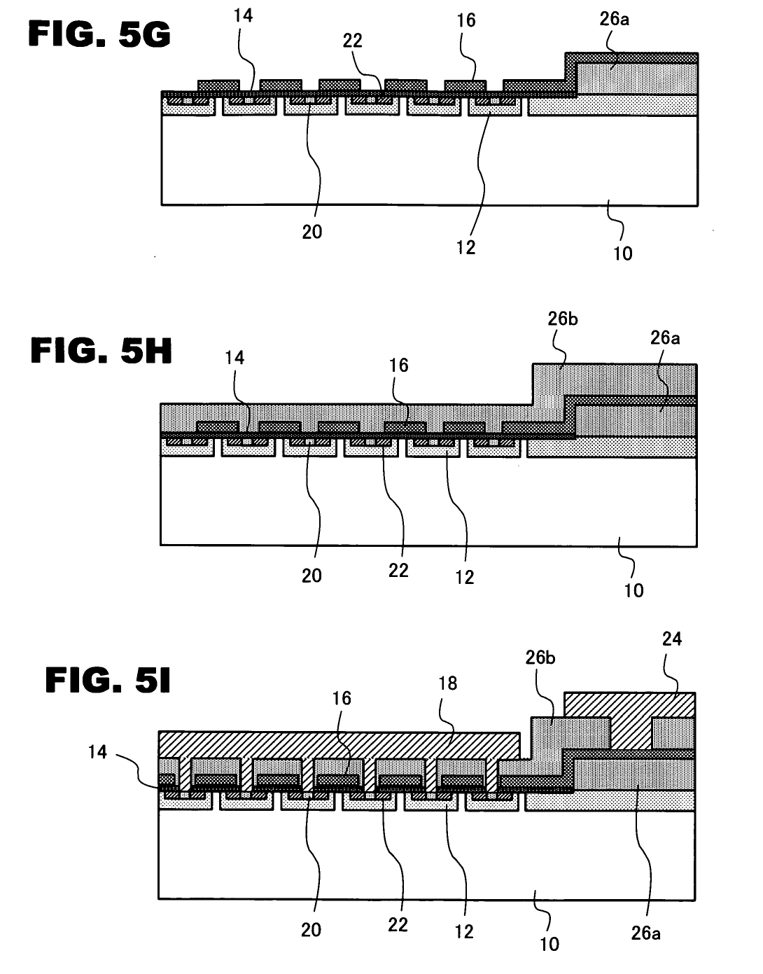

### DESCRIPTION OF THE REFERENCE NUMERALS

110: SiC SUBSTRATE
112: P-WELL REGION
114: GATE OXIDE LAYER
116: GATE ELECTRODE
120: P⁺ IMPURITY DIFFUSION REGION
122: N⁺ IMPURITY DIFFUSION REGION
130: EPITAXIAL Si LAYER
210: SiC SUBSTRATE
212: P-TYPE WELL REGION
214: GATE OXIDE LAYER
216: GATE ELECTRODE
220: P⁺ IMPURITY DIFFUSION REGION
222: N⁺ IMPURITY DIFFUSION REGION
230: EPITAXIAL Si LAYER

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

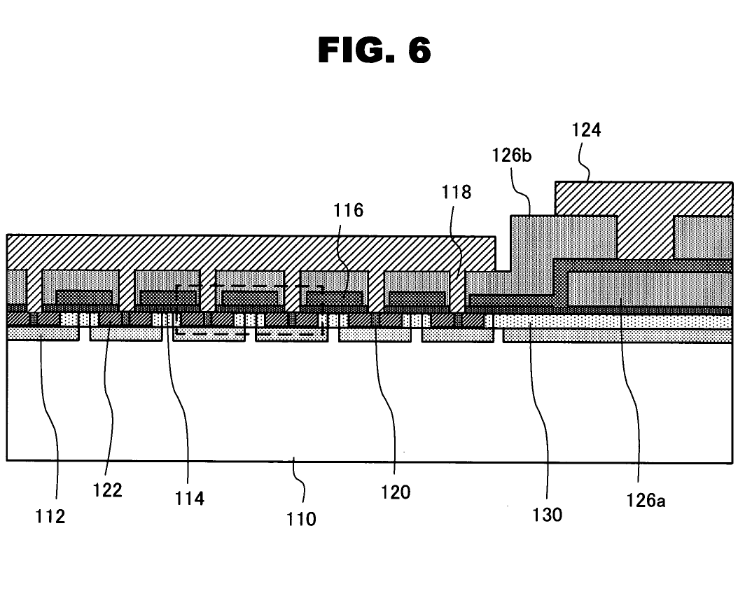

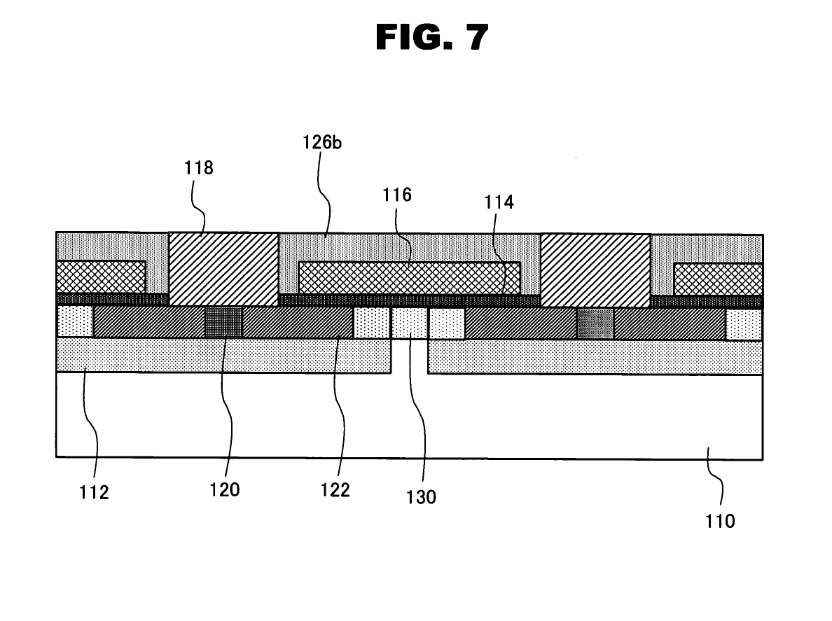

FIG. 6 and FIG. 7 illustrate a semiconductor device according to a first exemplary embodiment of the present invention. According to this embodiment, an N-type epitaxial Si layer (130) is formed after forming a P-well region (112). A MOSFET is formed in the N-type epitaxial Si layer (130). In these figures, an aluminum gate 124 and a source electrode (aluminum electrode) 118 is formed on an upper surface of the device, and a drain electrode (not illustrated) is formed on a lower surface of a substrate. Such a configuration allows an electrical potential of a strong electric field in the vertical direction between the source and the drain. An electrical potential of several hundred V to several tens kV is applied across SiC material junctions. Conversely, an electrical potential of several tens V applied to the aluminum gate 124 is used to switch the MOSFET on and off. In this case, an electric field of a maximum intensity of about 3 MV/cm is designed to be applied to a gate insulating layer 114.

FIG. 6 also illustrates an N-type SiC substrate 110, a P-type well region 112, a polysilicon gate electrode 116, a P⁺ impurity diffusion region 120, an N⁺ impurity diffusion region 122, and inter-layer insulating layers 126a and 126b.

FIG. 7 is a cross-sectional view enlarging the region defined by the broken line in FIG. 6, illustrating a vicinity of the gate oxide layer 114 on the N⁺ impurity diffusion region 122. However, the conduction types of the semiconductors (N-type and P-type) in the present invention may be reversed. Furthermore, a 3C—SiC (cubic silicon carbide) substrate, a 4H—SiC substrate, or a 6H—SiC substrate may be used for the SiC substrate 110.

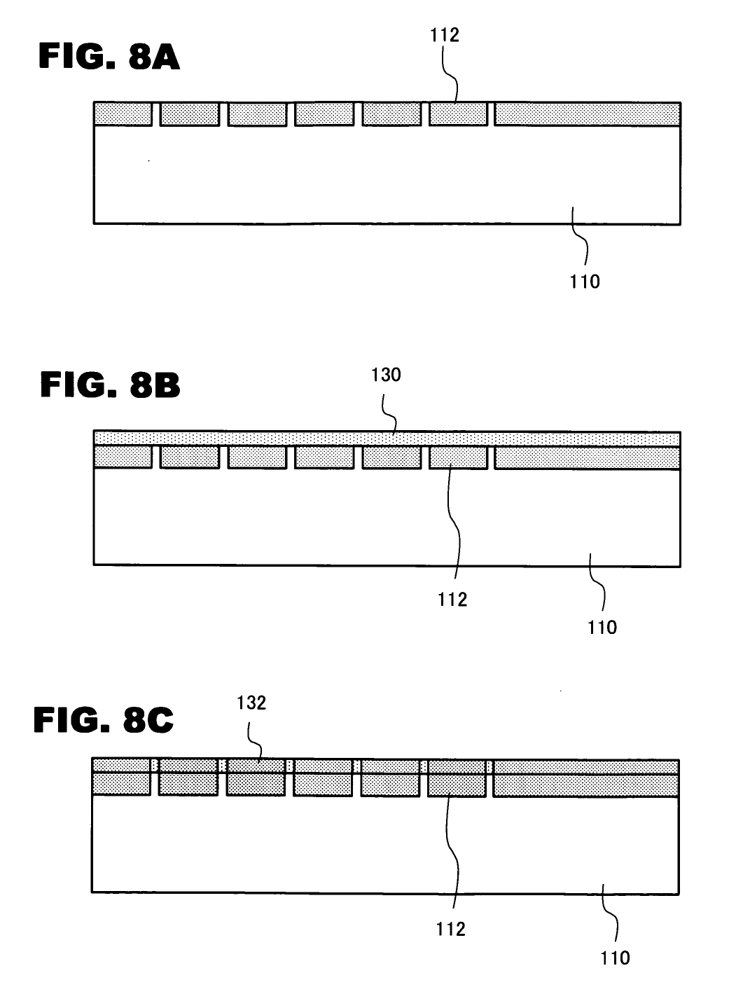

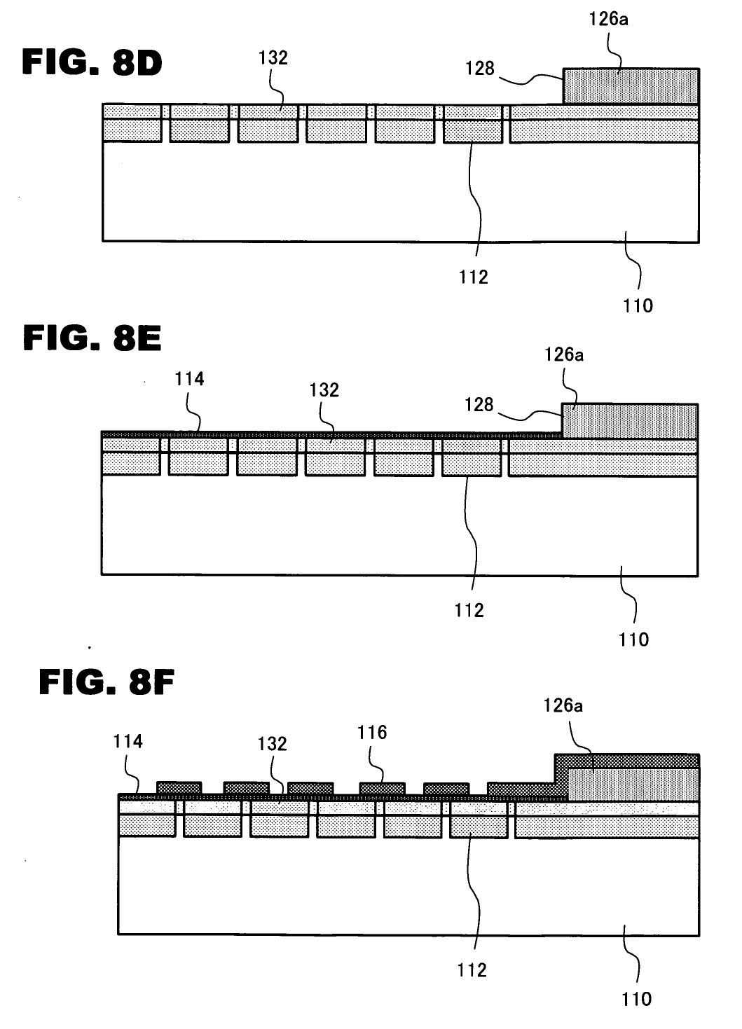

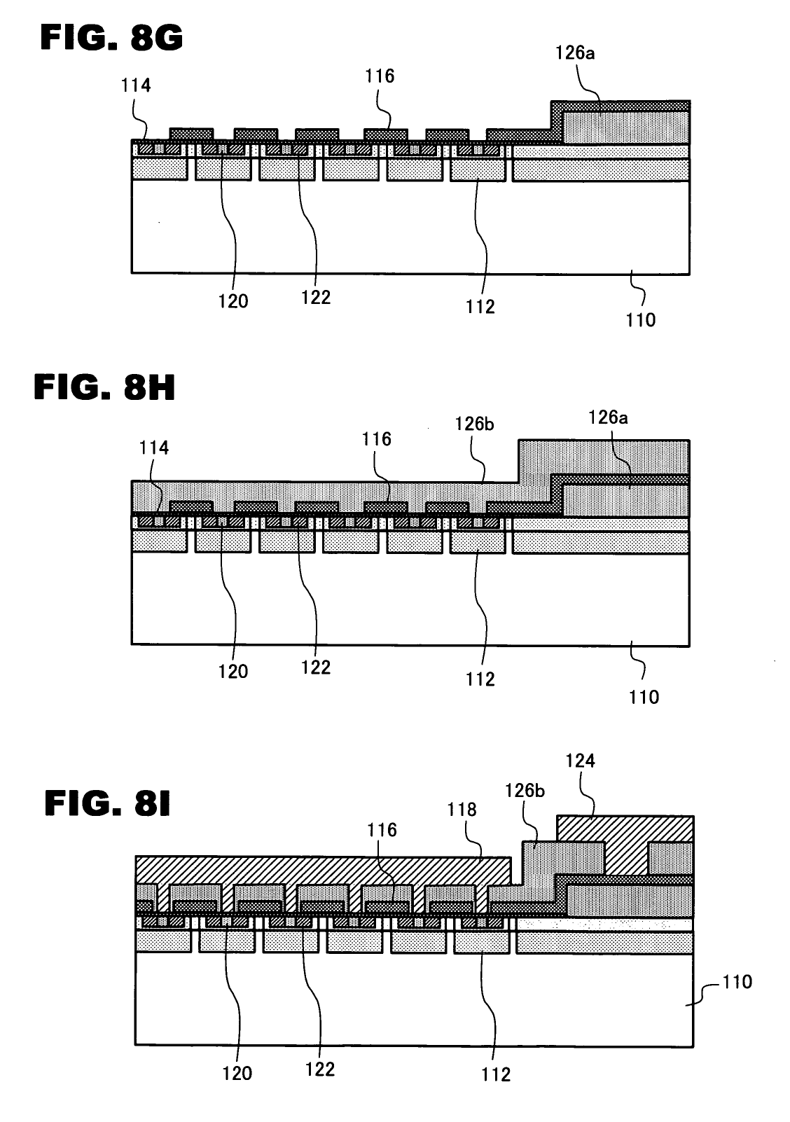

FIGS. 8A to 8I illustrate steps for fabricating a semiconductor device according to the first exemplary embodiment of the present invention illustrated in FIG. 6 and FIG. 7. A mask of a desired pattern (not illustrated) is formed on an N-type SiC substrate 110, and a P-well region 112 such as that of FIG. 8A is formed by ion injection, after which activation heat treatment is performed at about 1200 to 1800° C.

Then, an N-type epitaxial Si layer 130 is formed over an entire surface by well-known methods as illustrated in FIG. 8B. A P-type well region 132 is formed again in the epitaxial Si region 130 as illustrated in FIG. 8C, and active heat treatment is performed at about 1000° C.

Next, an inter-layer insulating layer 126a is formed to separate elements, and an aperture 128 is formed on an element region as illustrated in FIG. 8D. Then thermal oxidation treatment is conducted to form a silicon oxide layer 114 in the element region as illustrated in FIG. 8E. A polysilicon gate electrode layer 116 is formed (patterning) on the silicon oxide layer 114 by well-known methods as illustrated in FIG. 8F.

Then, as illustrated in FIG. 8G, an N⁺ impurity diffusion region 122 is formed in a self-aligning fashion by ion injection. A P⁺ impurity diffusion region 120 is formed likewise by ion injection. Thereafter, activation is performed at about 1000° C. Ion types may include aluminum to form the P-type regions and nitrogen and phosphorus to form the N-type regions. An inter-layer insulating layer 126b is formed next as illustrated in FIG. 8H. Finally, contact holes are opened, and source and gate aluminum electrodes 118 and 124 are formed as illustrated in FIG. 8I.

A semiconductor device fabricated by steps such as those recited above includes a gate oxide layer 114 formed on an epitaxial Si layer 130 as illustrated in FIG. 7, thereby greatly improving yield and reliability of the gate oxide layer 114. Oxide layers conventionally formed on SiC generally exhibit quality poorer than that of oxide layers formed on Si. This decrease in quality is due to such factors as (1) a typically very large number of defect regions in the SiC crystal causing insulator breakdown, (2) oxidation of SiC causing residual carbon thereby impairing insulating properties, and (3) thermal oxidation after ion injection resulting in detrimental effects by the injected impurities.

Furthermore, according to the first embodiment of the above stated present invention, because a MOSFET (source region) is formed in an epitaxial Si layer 130 the on resistance can be reduced compared to that of conventional art. In conventional configurations, the quality of an oxide layer on SiC is poor, and many interface levels and fixed charges exist in an interface between the SiC and the oxide layer. These phenomena cause higher resistance due to electron scattering when electrons move in the on state. In addition, heat treatment at high temperatures for activation of impurity s in SiC often roughen the surface, and it is thought that this roughened portion causes a higher resistance when electrons move.

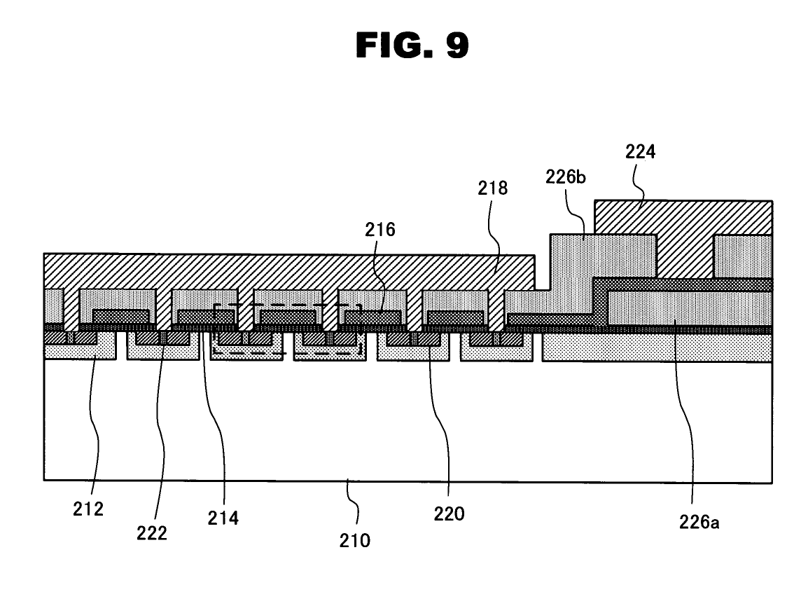

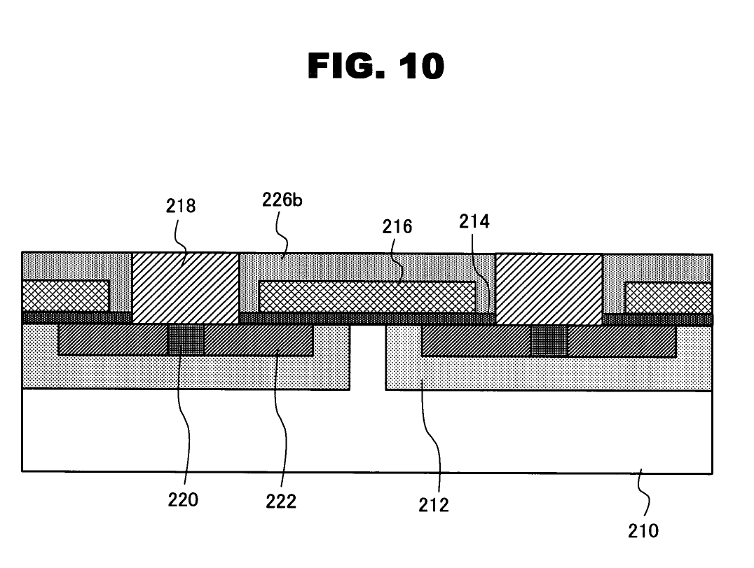

FIG. 9 and FIG. 10 illustrate a semiconductor device according to a second exemplary embodiment of the present invention. In this embodiment, a P-type well region 212 is formed in a SiC substrate 210. A portion is excavated in the P-well region 212 corresponding to a subsequent N⁺ impurity diffusion region 222 and a subsequent P⁺ impurity diffusion region 220. This excavation is filled with an epitaxial Si layer 230 or polysilicon.

As illustrated in FIG. 9, an aluminum gate 224 and a source electrode (aluminum electrode) 218 is formed on an upper surface of the device, and a drain electrode (not illustrated) is formed on a lower surface of a substrate. Such a configuration allows an electric potential of a strong electric field in the vertical direction between the source and the drain. An electrical potential of several hundred V to several tens kV is applied across SiC material junctions. Conversely, an electrical potential of several tens V applied to the aluminum gate 224 is used to switch the MOSFET on and off. In this case, an electric field of a maximum intensity of about 3 MV/cm is designed to be applied to a gate insulating layer 114.

FIG. 9 also illustrates the N-type SiC substrate 210, the P-type well region 212, a polysilicon gate electrode 216, the P⁺ impurity diffusion region 220, the N⁺ impurity diffusion region 222, and inter-layer insulating layers 226a and 226b.

FIG. 10 is a cross-sectional view enlarging the region defined by the broken line in FIG. 9, illustrating a vicinity of the gate oxide layer 214 on the N⁺ impurity diffusion region 222. However, the conduction types of the semiconductors (N-type and P-type) in the present invention may be reversed. Furthermore, a 3C—SiC (cubic silicon carbide) substrate, a 4H—SiC substrate, or a 6H—SiC substrate may be used for the SiC substrate 110.

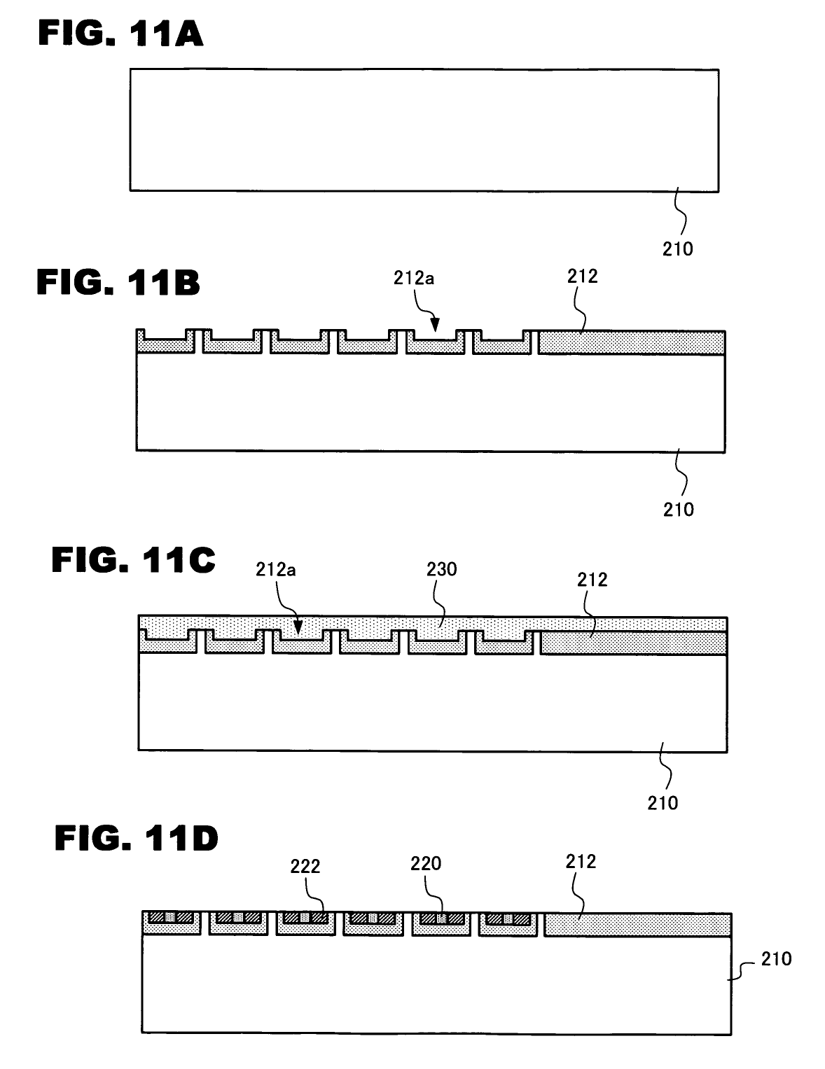

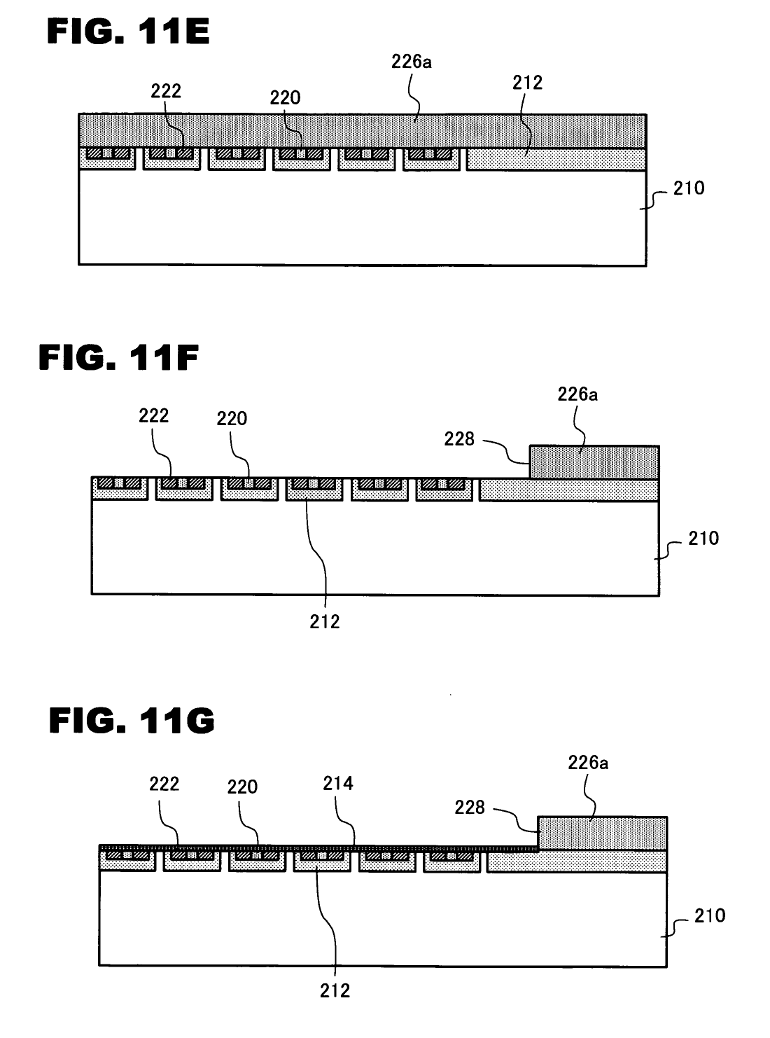

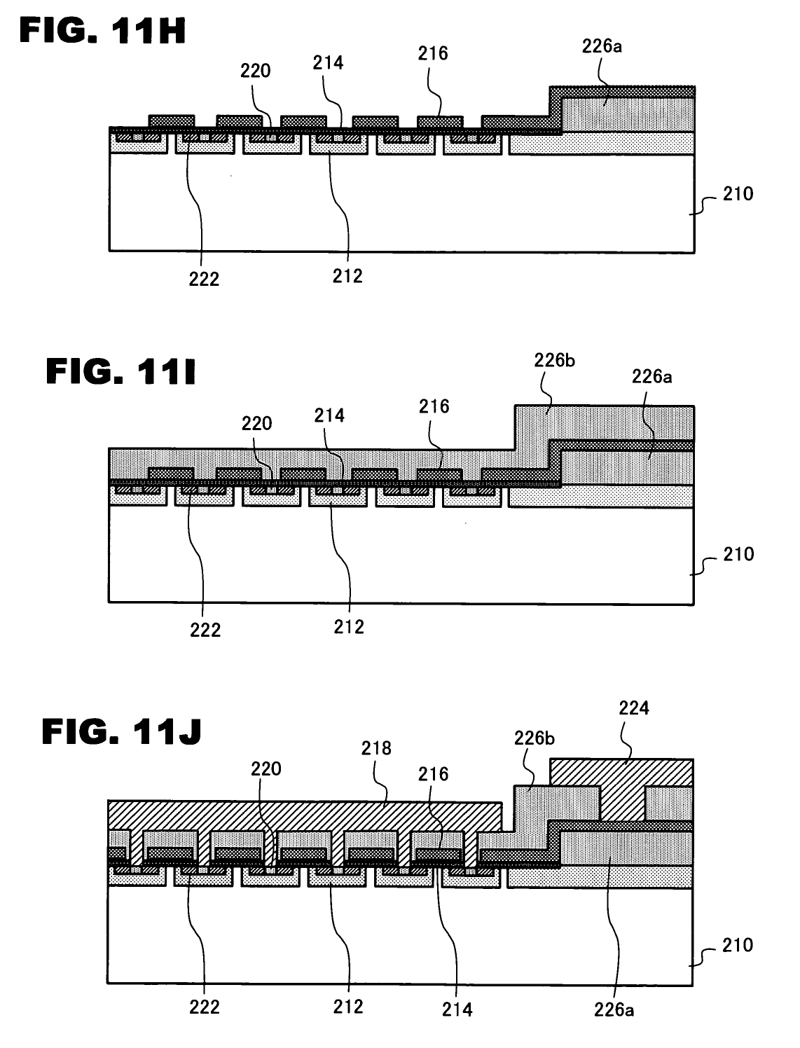

FIGS. 11A through 11J illustrate steps for fabricating a semiconductor device according to the second exemplary embodiment of the present invention illustrated in FIG. 9 and FIG. 10. A mask of a desired pattern (not illustrated) is formed on an N-type SiC substrate 210 such as that of FIG. 11A, and a P-type well region 212 is formed by ion injection, after which active heat treatment is performed at about 1200 to 1800° C. A trench 212a is formed in an interior portion of the P-well region 212, while leaving a remainder portion subsequently to form a MOSFET channel, as illustrated in FIG. 11B. An epitaxial Si layer 212 or polysilicon is formed over an entire surface of the SiC substrate 210 as illustrated in FIG. 11C.

Then, an upper layer of the epitaxial Si layer 212 is removed by CMP, leaving a portion in the trench 212a. An oxide layer mask (not illustrated) is formed to protect the portion that will become a P⁺ impurity diffusion region 220. By phosphorus thermal diffusion (by forming a PSG and heating at 1000° C. for 30 minutes), an N⁺ impurity diffusion region 222 is formed selectively in the epitaxial Si layer 212 (silicon portion). At this time, phosphorus does not diffuse into the SiC substrate 210. Boron injection and the like then form a P⁺ impurity diffusion region 220, and activation is performed, resulting in a configuration such as that illustrated in FIG. 11D.

Thereafter, an inter-layer insulating layer 226a is formed to separate elements as illustrated in FIG. 11E. The inter-layer insulating layer 226a is a SiO₂ layer, and for example, may be formed with a thickness of about 500 nm by plasma CVD using a mixed gas of TEOS and O₂ on a substrate at 400° C. An aperture 228 is formed on a portion corresponding to an element region as illustrated in FIG. 11F. A thermal oxide layer 214 is formed on a portion corresponding to the element region as illustrated in FIG. 11G.

Then, a polysilicon gate electrode layer 216 is formed (patterning) by well-known methods on the silicon oxide layer 214 as illustrated in FIG. 11H. CVD processing forms a SiO₂ inter-layer insulating layer 226b as illustrated in FIG. 11I. Finally, contact holes are opened, and aluminum electrodes 218 and 224 of a source and a gate 224 are formed as illustrated in FIG. 11J.

In this embodiment, the N⁺ impurity diffusion region 222 and the P⁺ impurity diffusion region 220, in the vicinity of the source of the SiC-MOSFET are formed by Si (230), and others are formed using SiC. Whereas the MOSFET channel region is Si (130) in the first embodiment, this embodiment has SiC as the MOSFET channel, so there is a merit in increasing the operation temperature to about 200° C.

Furthermore, the yield and reliability of the gate oxide layer 214 greatly improves for this embodiment similarly to that of the first embodiment due to formation of the gate oxide layer 214 on the epitaxial Si layer 230. In addition, because the MOSFET (source region) is formed in the epitaxial Si layer 130, the on resistance can be reduced compared to that of conventional art.

Although the embodiments of the present invention are described above, the present invention is in no way limited to these embodiments, and modifications can be allowed in a range of the technical ideas described in the scope of the patent claims.

For example, the epitaxial Si layer 130 of the first embodiment may be removed except for the portion of the N⁺ impurity diffusion region 122 and the P⁺ impurity diffusion region 120, thereby forming a MOSFET having a SiC channel region similar to that of the second embodiment. As a further example, the epitaxial Si layer may be replaced by a high quality Si monocrystal by using attachment technology.

In the second embodiment, the N⁺ impurity diffusion region 222 and the P⁺ impurity diffusion region 220 are formed prior to forming the gate electrode 216 as illustrated in FIG. 11D, but these two diffusion regions may be formed by ion injection after forming the gate electrode 216.

What is claimed is:

1. A semiconductor device comprising:
a SiC substrate;
an epitaxial silicon layer formed on a surface of the SiC substrate;
a silicon oxide layer formed on the epitaxial silicon layer;
a gate electrode formed on the silicon oxide layer;
a source region formed in the epitaxial silicon layer; and
a drain electrode connected to the SiC substrate.

2. The semiconductor device according to claim 1, wherein the SiC substrate is selected from a 3C—SiC (cubic silicon carbide) substrate, a 4H—SiC substrate, and a 6H—SiC substrate.
